(19) United States
(12) Patent Application Publication
(10) Pub. No.: US 2007/0209317 A1
(43) Pub. Date: Sep. 13, 2007

(54) THERMAL TRANSFER BARRIER BUILDING MEMBERS

(76) Inventor: Gary L. Jensen, Liberty Lake, WA (US)

Correspondence Address: WESLEY B. AMES, 7031 LOS VIENTOS SERENOS, ESCONDIDO, CA, 92029, US

(21) Appl. No.: 11/556,158

(22) Filed: Nov. 2, 2006

Related U.S. Application Data
(60) Provisional application No. 60/863,798, filed on Oct. 31, 2006.
(60) Provisional application No. 60/781,428, filed on Mar. 10, 2006.

(51) Int. Cl. C23C 14/56

(52) U.S. Cl. 52/736.3; 428/701; 427/178

(57) ABSTRACT

Process for forming building members from a metal coil is described, where the members have a thermal barrier coating on at least one contact or exposed surface. Such building members and apparatus for continuously coating and forming the members are also described.

### RELATED APPLICATIONS

This application claims the benefit of Jensen, U.S. Provisional Appl. No. 60/863,798, filed Oct. 31, 2006, and of Jensen, U.S. Provisional Appl. No. 60/781,428, filed Mar. 10, 2006, which are incorporated herein by reference in their entireties.

### FIELD OF THE INVENTION

The present invention relates to structural members and finish building components that include a thermal barrier coating.

### BACKGROUND OF THE INVENTION

The following discussion is provided solely to assist the understanding of the reader, and does not constitute an admission that any of the information discussed constitutes prior art to the present invention.

Commercial building construction (as well as some residential construction) commonly utilizes metal building members, including metal wall studs and other structural members, as well as a variety of finish members and heating, ventilation, and air conditioning (HVAC) components. A recognized property of such building members is their high thermal conductivity. In many cases the metal member provides an undesirable high thermal conductivity pathway between zones that have significantly different temperatures. For example, metal wall studs that have both interior and exterior wall surfaces fastened directly to the studs provide a direct path for thermal transfer that can significantly degrade the overall insulative performance of the wall despite the presence of insulation batts between the studs.

Some attempts have been made to provide reduced heat flow through wall studs, e.g., by creating hybrid steel/wood studs, by removing some of the steel in the web portion of the stud, and by reducing the contact area between the steel stud and the attached wall surface. None of these approaches have been widely adopted, with the result that the high thermal transfer properties of metal building members remains a major issue in construction use of those members and the design of buildings in which they are incorporated.

### SUMMARY OF THE INVENTION

The present invention concerns methods and articles that significantly reduce thermal transfer through building surfaces that include metal members, especially roll-formed and stamped members. Steel and other metal building construction has become increasingly important due to the advantages it confers. However, such construction has had a difficulty with higher than desired thermal transfer through the metal members. The present invention addresses this difficulty by using thermal barrier coatings such as thermal barrier paint coatings at exposed and/or contact surfaces of structural or architectural members in building construction. The thermal barrier coatings are applied prior to or during the production of the member, in contrast to application of coatings following installation of the building members in a building.

Advantageously, such thermal barrier coatings can be incorporated even on existing designs of structural building members. The result of this is that the resulting thermal barrier coated building members can be marketed without requiring separate structural testing or certification because they retain the structural properties of the uncoated member.

As discussed below, the thermal barrier coating can be applied at various points during the production process. The choice of coating application timing can be based, at least in part, on the ability of the coating to tolerate the bending needed in the forming process for the particular type of member and/or on production efficiency. Thus, the coating can be applied immediately following forming of metal sheet, e.g., before coiling. Coating can also be applied following coiling, followed either by re-coiling or by use of the coated sheet in forming products such as building members. Coating can also be applied during or following forming of such products, either as new coating, or as re-coating, e.g., to repair any damage to a coating that occurred during the forming process.

Thus, in a first aspect, the invention provides a process for preparing a building member by unwinding a metal coil of a particular thickness, coating at least a longitudinal band of the metal coil with a thermal barrier coating to provide a coated sheet, and roll-forming a building member from the coated sheet. The result is that the thermal barrier coating is present on at least one contact surface of the building member. Such thermal barrier coating can be applied either before and/or after the roll-forming is performed; when the coating is applied before the roll-forming, an additional thermal barrier coating can be applied after the roll-forming. Thermal barrier coating can be applied as one or more cumulative coats, e.g., 1, 2, 3, 4, or more coats. A range of thicknesses of metal coil can be coated, e.g., in the range of 0.0170-0.1770, 0.0220-0.1400, 0.0220-0.1100, or 0.220-0.800 inches to Most often the metal coil is a steel coil, e.g., of 26-10, 24-12, 24-14, or 20-6 gauge. The method can also include creating at least one opening in the member (e.g., an opening(s) suitable for wiring and/or plumbing runs), such as by punching (e.g., in a continuous operation as part of the forming process of the members).

The thermal barrier coating can be applied to the metal coil on one or both sides, and the band can be partial or full on one or both sides. In particular embodiments, the thermal barrier coating is a paint, e.g., containing hollow microspheres and/or infrared radiation reflective pigment or particles; a powder coating; a metal coating, e.g., a zinc or zinc aluminum alloy, which can be metallurgically bonded with the surface of the metal coil and/or can include hollow ceramic microspheres or other particles with low thermal conductivity; the thermal barrier coating includes an effective amount of a low thermal conductivity component and an infrared radiation reflective material. A thermal barrier coating can include two or more different coating layers of different types, e.g., a thermal barrier permanent metal coating and a thermal barrier paint coating. In many cases, the process will include cleaning the surface of the metal coil before coating is performed, e.g., removal of oxides, mill scale, dirt and other debris, and/or oils and other lubricants.

The process can be used to produce a large variety of building members, including structural, architectural, and cosmetic members, e.g., wall studs, purlins, joists, rafters, tracks, trusses, floor deck sections, roof pan sections, architectural roofing sections, siding sections, cladding, window frames, door frames, door panels (e.g., pedestrian entry or garage door panels), and sandwich panels which include at least one metallic layer (especially panels in which one or both outer layers are metallic).

In some embodiments, the thermal barrier coating reduces heat flow across the member by at least 5, 10, 15, 20, 30, 40, 50, or even greater percent as compared to members that are the same except that they lack any thermal barrier coating.

In certain embodiments, the present process is suitable for high production rates. Thus, in particular embodiments the process involves production of longitudinal roll-formed product at a rate of at least 100 linear feet per minute, e.g., at least 100, 150, 200, 250, 300, 350, 400, or 450 linear feet per minute, or in a range of 100-200, 200-250, 200-300, 300-400, 300-500, or 400-500 linear feet per minute.

It can be advantageous to supply metal coil already coated with a thermal barrier coating. Such a thermal barrier coated metal coil can then be used in forming or fabricating a variety of objects, particularly including support and other building members. Thus, another aspect of the invention concerns a process for finishing a metal coil that involves coating at least a longitudinal band of a metal strip of a particular thickness with a thermal barrier coating, and following that coating, coiling the coated metal strip into a coated metal coil. The metal strip can be supplied to the coating process as newly formed (e.g., newly rolled) sheet where the coating is part of a finishing process, or can be supplied as a coil that does not have the desired thermal barrier coating. When supplied as a coil, the coil will be uncoiled for supplying the metal strip to the coating process.

In particular embodiments, the metal strip is as described for the metal coil described in the above aspect or otherwise described herein. Similarly, in particular embodiments; the thermal barrier coating and/or the surface preparation, and/or the metal strip is prepared for coating as described for the above aspect or otherwise described herein.

Metal coil pre-coated with a thermal barrier coating can advantageously be used to make articles such as building members. Thus, a related aspect of the invention concerns a process for making a building member by forming a thermal barrier coated metal coil (e.g., steel coil) of a particular thickness into a building member. Suitable forming methods include, for example, roll-forming and stamping.

In particular embodiments, the metal coil, thermal barrier coating, the method of applying the thermal barrier coating, and/or the type of building member made is as indicated for other aspects herein, or otherwise described herein.

The invention also provides materials and building members coated with a thermal barrier coat as described herein, e.g., as produced by the methods described in preceding aspects.

Thus, another aspect of the invention concerns a thermal barrier coated metal coil (e.g., a steel coil), where the coil includes at least a longitudinal band coated on at least one side with a thermal barrier coating. Such longitudinal band can be on one side or both sides, can be the same or different widths on each side, and can cover essentially any desired fraction of the width of a side, e.g., 5-20, 10-25, 20-35, 35-55, 50-80, 80-100, or 100 percent of one or both sides.

In particular embodiments, the thermal barrier coating, the type of metal coil, the thickness of the metal coil, and/or the width of the metal coil is as indicated for the preceding aspects or otherwise described herein.

Similarly, in a related aspect, the invention provides a roll-formed metal (e.g., steel) building member, where the member includes a thermal barrier coating on at least one surface. Such coated building member is coated before installation, e.g., shop or factory coated rather than being coated on-site or after installation. Such a building member may be of various types, e.g., a structural member (which is preferably coated on a contact surface or at least on one, often two or more contact surfaces), an architectural member, or a finish member.

In particular embodiments, the thermal barrier coating, the type of structural member, and/or the type of metal are as described for aspects above or otherwise described herein.

One particularly advantageous type of structural member includes additional features to reduce heat flow across the member. For example, such members can include wall studs, purlins, rafters, trusses, joists, and the like. Many such members include two peripheral flange sections and a web section between them. Two particular exemplary features that can be incorporated are a perforated web section, and concave shaped peripheral flanges or other contact surface. Either or both of these features can be incorporated in a member.

Such concave contact surface shape can create a channel or channels; such channel(s) can be filled with thermal barrier coating, e.g., a coating at least 0.009, 0.020, 0.030, 0.040, 0.050, 0.060, 0.070, 0.80, 0.090, 0.10, 0.20 inch thick. For members having two contact surfaces, e.g., peripheral flanges, one or both flanges can have the concave or channel shapes and one or both cavities or channels can be filled.

In the case of wall studs, such modification can be sufficient so that the heat flow through the stud is less than the heat flow through an average 2×6 fir stud.

A related aspect concerns a building finish component or member that includes a formed metal surface coated with a thermal barrier coating. Examples include door and/or door facing panels (e.g., residence and garage doors and panels), roofing sections or shingles, and siding sections. In particular embodiments, the metal and/or the thermal barrier coating is as described for aspects above or otherwise described herein.

Yet another aspect concerns a steel coil processing system that includes a coil handling mechanism and a thermal barrier coating system which applies the thermal barrier coating material to the steel coil. The thermal barrier coating system can include a paint sprayer, a metal sprayer, a hot dip tank, and/or other component suitable for applying a particular thermal barrier coat.

In particular embodiments, the steel coil processing system can also include one or more of a thermal barrier coating material reservoir, at least one thickness roll that reduces the thickness of a steel sheet (hot and/or cold rolling), a coil straightener, a coil slitter, a steel surface cleaning system, a roll-forming line, a stamping station, sheet metal brake, a re-coiler.

In particular embodiments, the system will produce roll-formed longitudinal building members at a rate of at least 100, 150, 200, 250, 300, 350, 400, or 450 linear feet per minute, or in a range of 100-200, 200-250, 200-300, 300-400, 400-500 linear feet per minute.

In addition to the building members specified above, the present invention also provides fasteners which have thermal barrier coatings, as well as methods in which such fasteners are used in fastening the present building members, e.g., together and/or with other building materials. Such fasteners are coated on one or more surfaces with a thermal barrier coating as described herein, preferably at least one the surface(s) which will be in contact with metal building members.

Thus, in particular embodiments, the fastener is a screw (e.g., drywall screw or screw for fastening metal building members together), a bolt or cap screw, or nut, a washer, or a clip or snap fastener; the thermal barrier coating is as specified for one of the above aspects, e.g., the coating is or includes a thermal barrier paint coating, a powder coating, and/or a metal coating. In particular embodiments, a screw fastener has a thermal barrier coating on the entire threaded portion, at least on the portion of the threads which will be in contact with a metal building member following normal installation, on at least the portion of the threads which will be in contact with a metal building member following normal installation and not on at least a portion of the threads which will not be in contact with a metal building member following normal installation; on at least the contact portion of the screw head; on at least the contact portion of the screw head and on the contact portion of the threads; on at least the contact portion of the head and on the full threads; on the entire screw. Similarly, for cap screw and/or bolts, in particular embodiments with respect to coating with a thermal barrier coating, at least the portions of the cap screw or bolt which will be in contact with metal building members during normal use are coated; at least the contact portion of the head (as normally installed) is coated; at least the contact portion of the head and at least the penetrating portion of of the cap screw is coated; the entire cap screw is coated.

For specification of percentage reduction in heat flow across a member, the heat flows are tested with the higher temperature source on the side of the thermal barrier coating (or more effective thermal barrier coating as applicable) at a temperature of 90 degrees F. and the lower temperature side at 70 degrees F.

The term “building member” is used to refer to elements that are used in construction of buildings, e.g., commercial and residential buildings. Such building members include structural members, finish members, such as architectural members, ventilation members such as heating and air conditioning ducts. In this context, the term “structural member” refers to building components that are utilized to give strength and/or overall shape to the building structure rather than primarily to provide exterior protective and/or aesthetic covering. Nonetheless, such structural members may be visible and may contribute to the appearance of the structure. As used herein, “finish members” are building members that primarily provide building covering, small area covering, and/or closure of a barrier in a building. Examples include doors and windows and components thereof, as well as building siding and roofing pieces. One class of finish member is architectural members. As used herein, the term “architectural members” refers to building finish members that primarily provide exterior covering, e.g., roofing and siding. Such architectural members may provide a degree of strength and shape to the building, but such function is secondary to the covering function. In certain type of metal building construction, some building members may have both significant structural and architectural roles, e.g., the metal skin in single layer metal storage or shop buildings. In those cases, such building member will be deemed an architectural member. As indicated above, “ventilation members” refers to components of building air transport systems, especially including heating and air conditioning system ductwork.

As used herein the term “coil” refers to a roll of metal sheeting, especially steel sheeting.

In the context of construction of building members from metal stock, the term “forming” refers to sheet metal shaping, e.g., by methods such as roll-forming, stamping, and the like.

The term “roll-forming” is used in its usual sense to refer to a method for shaping metal sheet, e.g., steel sheet, using sets of rollers to create longitudinal bends in the sheet

As used herein, the term “thermal barrier coating” refers to a layer over a substrate, e.g., a metallic sheet substrate that substantially reduces thermal transfer across the coated surface of the substrate. Such thermal barrier coating has a thermal conductivity that is no more than 1/10 the thermal conductivity of the substrate on which it is applied. Usually a thermal barrier coating will have a thermal conductivity of less than 0.4 W/m·K (W˜m⁻¹·K⁻¹). In many cases, the thermal conductivity of the coating will be less than 0.1, 0.08, 0.06, 0.05, 0.04, 0.03, or 0.02 W·m⁻¹·K⁻¹.

Additional embodiments will be apparent from the Detailed Description and from the claims.

### BRIEF DESCRIPTION OF THE DRAWINGS

FIG. 1 schematically shows a metal substrate coated with multiple layers of thermal barrier coating.

FIG. 2 show cross-sectional profiles of three exemplary structural members useful in the present invention that are typically formed by roll forming: A. Z-member, B. C-member, C. U-member (e.g., a track).

FIG. 3 shows cross-sectional profiles of three exemplary roofing panels, an exemplary wall stiffener section, and an exemplary floor deck section that are typically formed by roll forming: A. standing seam roofing, B. simple corrugated roofing, C. spaced rib roofing, D. wall stiffener, and E. floor decking.

FIG. 4 shows an exemplary roll formed emergency egress opening frame illustrating placement of a peripheral thermal barrier coating.

FIG. 5 schematically shows different locations on a steel framed building where use of thermal barrier coated structural members provides an advantageous thermal barrier.

FIG. 6 illustrates a simplified version of a combined roll forming and thermal barrier coating line. A. top view, B. side view.

FIG. 7 illustrates a simplified version of a thermal barrier coating system that includes an uncoiler, a sprayer that can spray bands of coating on one or both faces of a metal coil, and a re-coiler. A. top view, B. side view.

FIG. 8 illustrates a simplified version of a thermal barrier coating systems that includes an uncoiler, a coating bath, e.g., a hot dip bath, and a re-coiler. A. top view, B. side view.

FIG. 9 shows a cross-section of a portion of a sandwich panel having thermal barrier coatings on the exterior surfaces and a foam core.

### DETAILED DESCRIPTION OF THE PREFERRED EMBODIMENTS

Building using metal (especially steel) components in both commercial and residential construction has become very widely used. Support members used for such construction include, for example studs, purlins, top and bottom plates, joists, rafters, tracks, trusses, floor decks, roof pans, and the like. In addition to such structural components, various finish or architectural components are also often formed of steel or other metal. Such components include, for example, roofing sections or shingles, siding sections, window and door frames, doors, door panels (e.g., residence and garage doors and panels), emergency egress opening frames, and the like.

Despite the various advantages offered by using steel or other metal construction components, a commonly recognized disadvantage is the interior heat loss (or gain) due to the rapid heat flow through the metal members. For example, steel studs penetrating a wall provide an efficient thermal transfer path across the wall, and can even cause thermal banding of wall coverings. Similar heat flow can also occur with other metal building members, with the severity of the heat flow depending the placement and construction of the member, and the type and extent of contact between the metal member and other building materials.

The present invention is able to provide a substantial reduction in heat flow across such metal building members by including a thermal barrier coating on at least one surface of a member that would otherwise provide an efficient heat flow path. For example, steel studs (e.g., C- or Z-purlins or studs) normally provide an efficient heat flow path across the studs passing from one wall contact flange through the web to the opposite wall contact flange, effectively bypassing insulation placed between the studs. Such heat flow can be significantly interrupted or reduced by coating at least one, and preferably both contact flanges, with a thermal barrier coating such as a thermal barrier metal coating and/or a thermal barrier paint. Such coating can be supplemented by design selections for the member, such as by reducing the direct-to-metal contact area between the metal member and other connected building components and/or by reducing the heat flow path available across the metal member, e.g., by using openings in the web of a stud or other similar member.

Applying such coatings to existing designs and close derivatives can be particularly beneficial because the resulting coated members can be marketed with no delay. This is because no testing is required for structural integrity of such members. The members can thus be offered “pending certification of thermal certification” in accordance with Steel Stud Manufacturers Associations [SSMA]. This allows immediate market entry and consequent energy savings, benefiting contractors, consumers, and communities world wide.

Coating building members as part of the process or producing the members is highly advantageous because of greatly enhanced efficiency as compared to on-site coating. The members can be used in construction using essentially the same procedures as used for conventional un-coated members. As a result there is no need for a special painting or coating steps during building construction, so that the use of the present thermal barrier coated members does not adversely affect the rate and cost of construction.

The thermal barrier coatings generally provide the advantageous thermal barrier properties by reducing thermal conduction and radiation across the coating and therefore across the coated member. Recognizing that heat reflects the vibrational and kinetic motion of atoms and molecules in a medium, heat flow is reduced by providing a medium in which transfer of such particle motion is reduced. Over distance scales described by classical physics, the thermal conductivity will generally involve thermal conductivity of solid components, thermal conductivity through gas (e.g., air, replacement gas, and/or partial vacuum), and radiative transfer.

In most cases, the reduction in thermal conductivity is accomplished by using materials that contain components that reduce the area through which efficient conduction can occur. For example, materials can be used that provide small area contacts, which can be made of materials that have low inherent thermal conductivity and/or can be evacuated. Such materials include foams and materials containing a high proportion of hollow micro- or nanospheres.

As indicated above, the high thermal conductivity of metal creates the problem of high heat flow through metal building members such as metal studs. In gases, in the absence of bulk flow of the gas (e.g., through convection currents) heat transfer is primarily by transfer of kinetic energy through collisions of gas molecules, while for non-metal solids heat is transferred through lattice vibrations (often referred to as “phonons”. The higher thermal conductivity of metals is due to the same mobile electrons which are involved in electrical conduction. Classically heat flow is approximated by the equation

(ΔQ/ΔtA)=−κ(ΔT/Δx)

where the left term is power per unit area, κ is the thermal conductivity for the material, and ΔT/Δx is the temperature gradient. For metals, the thermal conductivity increases with the temperature, while the electrical conductivity decreases, a relationship expressed in the Wiedemann-Franz Law as

κ/σ=LT

where κ is the thermal conductivity, σ is the electrical conductivity, T is the temperature, and L is the Lorenz number or Lorenz constant.

As indicated above, the present thermal barrier coatings have very low thermal conductivities due the low areas combined with long paths for heat flow. The thermal conductivity can be further reduced by using materials having inherently low bulk material thermal conductivity, appropriately sizing components such as microspheres to minimize kinetic energy transfer, and using IR reflective materials to reduce heat transmission due to radiative heating. The present coatings can have thermal conductivities of under 0.05 W/mK, or even less, e.g., under 0.04, 0.03, 0.02, or 0.015 W/mK.

For thermal conductivity in most porous materials (e.g., common insulations), a large fraction of the thermal conductivity is due to kinetic transfer due to gas molecules in the pores colliding with other gas molecules. In the best cases, such materials can approach the thermal conductivity of air. However, when the pores enter the sub-micron size range, the behavior can change, such that nanoporous materials (e.g., nanoporous polymers and other materials containing similar sized gas spaces, can be used as thermal insulation materials. In particular such materials can be used in the present invention.

Such nanoporous materials can achieve further reduction in thermal conductivity by taking advantage of the Knudsen effect. As indicated above, the thermal conductivity of insulation materials is due to conductive heat transfer through the solids, through kinetic transfer involving gas molecules that occupy the pores, and due to radiative transport. In contrast to conventional porous materials, e.g., polymer foams, where the major contribution to the thermal conductivity is due to intermolecular collisions between gas molecules within the pores, reducing the pore sizes to nanometer scales increases the collisions between the gas molecules and the pore walls, i.e., Knudsen effect, because the size of the pores is on similar scale to the mean free path for the gas molecules. The result of this effect is a reduction in the overall thermal conductivity of the material. In order to maximize the insulative effect, the porosity in such nanoporous materials should be as high as possible in order to reduce the contribution due to heat conduction through the solids (e.g., binders and microsphere walls for materials that include hollow microspheres). Thus for effective thermal insulation, materials with high porosity (e.g., ≧90%) and nanoscale (e.g., ˜100 nm) pores are beneficial.

Additional useful discussion of the behavior of nano-materials is provided in a variety of books and publications. In particular, useful discussion is provided in Drexler; 1995, Nanosystems: Molecular Machinery, Manufacturing, and Computation; John Wiley & Sons, New York, N.Y., particularly chapters 2, 4, 5, 7, 10, and 11.

### A. Exemplary Coatings

A number of different types of thermal barrier coatings can be utilized, for example, paint-type coatings, polymeric coatings, phosphate bonded composite coatings, thermal coatings, powder coatings, and metal coatings. In many cases, the coating will include hollow microspheres and may also include infrared reflective components. Such coatings are adhered to the metal substrate to create a persistent coating. Advantageously the coating is strongly bonded or fused to the substrate surface. It is also beneficial in many cases to select a coating provides substantial corrosion resistance properties to the coated metal.

Thus, for example, the invention can utilize coatings as described in Skelhorn, U.S. Patent Publ. 2005/0126441, entitled “Composition of a Thermally Insulating Coating System”, which is incorporated herein by reference in its entirety. As described therein, the thermal barrier coating can include a combination of materials described below used as a pigment and/or extender pigment (filler) system to produce an infrared reflective effect in conjunction with a low thermal conductivity in a filled composite. Such coatings may be applied to a variety of substrates, e.g., metal coil materials or formed metal building members, either alone or in combination with a thermal barrier primer.

Such paint type thermal barrier coatings generally contain two or more materials from the following groups of materials:

1) Extender pigments having high infra red reflectivity relative to reflectivity in the visible electromagnetic radiation region (i.e. has an Infra Red Reflectivity Index greater than 1.0).

2) Hollow micro-spheres, e.g., glass, ceramic, and/or organic polymer microspheres. Hollow micro-spheres have been found to be particularly useful in reducing thermal conductivity of the coating. Examples of hollow micro-spheres include glass microspheres of various glass compositions and having various microsphere diameters and diameter to wall thickness values (e.g. 3M Scotchlite micro-spheres). Other examples include ceramic micro-spheres (e.g. 3M's Z-light Spheres, Cenospheres, fly ash), or micro-spheres based on organic polymer composites, such as polymers or copolymers of acrylic materials that may be in dry powder or dispersed in an aqueous carrier (e.g. Rhopaque by Rohm and Haas), or based on copolymers of vinylidene chloride and acrylonitrile (e.g. Expancel by Expancel, Inc.). It is desirable to use materials with thermal conductivity values below 0.3 W·m⁻¹·K⁻¹, and preferably below 0.2 W·m·⁻¹·K⁻¹ and most preferably below 0.1 W·m·⁻¹·K⁻¹.

Particularly advantageous microspheres are evacuated microspheres, e.g., as described in Martin et al., U.S. Pat. No. 5,713,974 (which is incorporated herein by reference in its entirety). Additional descriptions of useful evacuated microspheres and microspheres filled with low thermal conductivity gas are provided in Torobin, U.S. Pat. No. 4,303,732, Coxe, U.S. Pat. No. 3,607,169, Sowman, U.S. Pat. No. 4,349,456, Manabe et al, U.S. Pat. No. 4,693,739, and Downs & Miller, U.S. Pat. No. 4,336,338, all of which are incorporated herein by reference in their entireties. Hollow metal microspheres can also be used, e.g., as described in Torobin, U.S. Pat. No. 4,415,512 (incorporated herein by reference in its entirety). Particle size and size distribution can be selected as desired, but in certain embodiments, such microspheres are 0.5 to 500 microns, 2 to 200 microns, 1 to 100 microns, or 5 to 50 microns average particle size, e.g., as measured by microscopy. Hollow glass and ceramic microspheres are available commercially from a number of different sources, e.g., from Hy-Tech, Melbourne, Fla.; Tech Traders, Vero Beach, Fla.; and 3M Corporation, among others

3) Infra-red reflective primary pigmenting materials. These are typically complex calcined metal oxide compositions, a number of which are specifically promoted for their infrared reflective qualities. Exemplary infra red reflective pigments of various compositions are described in U.S. Pat. Nos. 6,174,360 and 6,454,848 (which are incorporated herein by reference in their entireties) which are designed to have high reflectivity in the infrared region of the spectrum, and which are typically solid solutions having corundum-hematite crystalline structure containing guest component metal oxides.

A range of products under the GEODE, “Cool Colors” and “Eclipse” brands by Ferro Pigments have been identified as being particularly advantageous. The range of reflective pigments available allows for a complete color range to be developed, by mixing different pigments according to normal color formulating practices. These infrared reflective pigments may be complemented by use of conventional pigment systems which do not exhibit high infra red reflectivity if necessary to achieve specific visible (color) effects. Particular exemplary IR reflective products include: V-778 IR Brown-Black, V-780 IR Brown-Black, V-797 IR Black, V-799 Black, F-5686 Turquoise, PC-9158 Autumn Gold, PC-9416 Yellow, V-9250 Bright Blue, V-9248 Blue, V-9415 Yellow, 10201 Eclipse Black, 10202 Eclipse Black, 10203 Eclipse Blue Black, 10241 Forest Green, 10411 Golden Yellow, 10415 Golden Yellow, 10364 Brown, 0-1775B Black, V-12112 Bright Golden Yellow, V-12600 Cobalt Green, V-12650 IR Green, V-13810 Red.

Such thermal barrier coatings can be prepared according to conventional formulation principles using materials that are selected to have high infra red reflectivity and/or low thermal conductivity as described. The thermal barrier coating may, for example, be water based or organic solvent-based, single component or multi-component paint or polymer system, or a cement or gypsum based system. This variety of formulations is available because the thermal barrier properties are a function of the reflectivity and/or thermal conductivity of the components rather than the binder systems.

The thermal barrier coatings may be applied as one or two, or even more layers. The number of layers and/or the final coating thickness may be selected based on desired properties, e.g., insulating value, mechanical properties, drying time, and the like.

For many coating and substrate selections, it may be desirable to utilize a primer layer, which may be a thermal barrier primer in order to provide the level of adhesion and/or chemical separation useful to provide compatibility between the substrate and the surface thermal barrier coating.

Where a thermal barrier primer is desired, it is advantageous to incorporate components providing low thermal conducting and/or infra red reflectivity as indicated for surface thermal barrier coatings. For example, hollow microspheres can be used to reduce the thermal conductivity.

Thermal barrier paints and primers can be applied by conventional painting methods, such as spray, roller, and immersion coating methods.

For example, Innes, U.S. Pat. No. 5,807,434 describes a method for continuous two-sided paint application. Levendusky, U.S. Pat. No. 5,919,517 describes a method for continuous application of a thermoplastic polymer resin coating to a metal strip. Brugarolas et al., U.S. Pat. No. 5,039,360 describes a method for continuous application of a paint to a heated metal surface using a spray gun. Friedersdorf et al. U.S. Pat. No. 6,428,851 describes a method for coating a metal surface, particularly applicable to zinc and zinc alloy coated surfaces, using thermal deposition to apply a primer and/or finish coat. Each of these patents is incorporated herein by reference in its entirety. These and other similar application processes can be used to apply thermal barrier coatings as described herein.

Likewise, Friedersdorf et al., U.S. Pat. No. 6,428,851 describes a method for continuous deposition of a coating on a substrate. Friedersdorf et al., U.S. Appl. Publ. No. 2002/0114884 describes processes for applying a metal coating and an organic primer in a continuous process, and for coating a pre-primed metallic coated sheet. Each of these references is incorporated herein by reference in its entirety, and can be used for applying thermal barrier coatings.

Another example of application methods is described in Strutt et al., U.S. Pat. No. 6,579,573 (which is incorporated herein by reference in its entirety) in which nanoparticle liquid suspensions are applied using a thermal spray system. The nanoparticle suspension can involve hollow spherical shells. In one example, direct injection of the hollow shells with particles that melt in the flame or plasma results in a coating of the hollow shells in a binding matrix.

An example of a method for continuous application of a powder coating on metal strip is described in Lessmeister et al., U.S. Patent Appl. Publ. 2001/0046555, which is incorporated herein by reference in its entirety.

As indicated above, in addition to paint-type thermal barrier coatings, additional coatings such as bituminous and cementitious coatings can similarly be produced, e.g., using low thermal conductivity components such as hollow microspheres (IR reflective materials may also be added).

Yet another type of coating that can be used is a phosphate bonded composite that contains insulative components such as hollow ceramic microspheres and infrared reflective components.

Still another material that can function as a thermal barrier is a metal foam, e.g., an aluminum or aluminum alloy metal foam as described in Knott et al., U.S. Pat. No. 6,942,716.

For high build or filler applications, a material such as that described in U.S. Pat. No. 5,888,642 can be used (incorporated herein by reference in its entirety). The material described therein is referred to as a syntactic foam, and is formed from a mixture of hollow ceramic microspheres and a dry resin binder.

In addition to thermal barrier coatings such as those indicated above, permanent thermal barrier coating can also advantageously be used, either alone or in combination with the more readily removed coatings such as paint-type thermal barrier coatings. An advantageous type of such permanent coating is a metal coating, including metal coatings that metallurgically fuse with the substrate metal (e.g., steel). Common types of metal coatings, especially for ferrous substrates, are zinc, aluminum, and zinc/aluminum alloy coatings. Such metal coatings typically have the further advantage of providing corrosion resistance characteristics. Thus, for example, zinc, aluminum, or a zinc/aluminum alloy (e.g., GALFAN® or GALVALUME®) containing a large number of hollow ceramic microspheres can be applied to a steel surface such as the surface of a steel coil or a building member formed from such steel coil. Zinc/aluminum alloys suitable for coating steel are described, for example, in U.S. Pat. Nos. 4,448,748, 3,343,930, and 3,393,089, each of which is incorporated herein by reference in its entirety.

One way of applying such a thermal barrier metal coating is with metal spraying (also referred to as metallizing) (e.g., zinc spraying or zinc alloy spraying), where the sprayed metal includes a high concentration of hollow ceramic microspheres or other such component that reduces heat flow. Such spray may be applied directly to the steel surface or may be applied over a base coating. For example, a relatively thin base coating (e.g., less than 50 micrometer) may be applied using a hot dip or electroplating method. The resulting coated steel can be further coated with a thermal barrier coating using zinc or a zinc alloy containing a high concentration of hollow ceramic microspheres. Advantageously, a relatively thick layer of the thermal barrier coating can be applied, e.g., greater than 100, 200, or 300 micrometer.

Other application methods for metal coating can also be used in which low thermal conductivity components (e.g., hollow ceramic microspheres) are deposited on the surface. In particular, hot dip metal coating (e.g., using zinc, zinc alloy, or aluminum) can be used, where the molten metal contains a high concentration of hollow microspheres (e.g., hollow ceramic microspheres). Additional components that reduce thermal conductivity can also be included in the metal.

In the context of the above discussion, hot dip zinc coating (i.e., hot dip galvanizing) is commonly used, and a variety of different apparatus and methods have been described for such application. In this process, the zinc and steel form a metallurgical bond. The thickness of a hot-dipped coating can be varied from a thin zinc/iron alloy layer to heavy applications suitable for extended outdoor exposure. Such coating can be applied as part of a finishing process in steel sheet or coil manufacture, or can be applied to formed objects. In either case, the galvanized coatings are applied with cleaned steel sections or continuous coil passing into the galvanizing bath. This coating is usually measured as thickness or as coating mass in grams per square meter and ranges from a minimum of about 100 g/m² upwards, with an average around 175 g/m².

In some cases, such hot dip zinc coating is heat treated to form a galvanneal surface in which the zinc coating has been changed into a zinc-iron alloy coating, e.g., for improved paintability. As it leaves the bath of molten zinc the zinc coated sheet is immediately subjected to a heat treatment that causes the zinc to alloy with the iron and become a zinc-iron alloy coating.

Among the zinc/aluminum alloys, Galfan® is a zinc alloy coating (5% aluminum) with improved corrosion resistance and formability compared to zinc alone. It was discovered that by combining 95% zinc with nearly 5% aluminum plus small quantities of rare earth mischmetal, the alloy could be reliably used in the hot-dip coating process (and other coating processes), and conferred substantially improved performance to the end-product. Such alloys are described in U.S. Pat. No. 4,448,748 which is incorporated herein by reference in its entirety.

Another useful zinc/aluminum alloy is Galvalume®, which contains 55% aluminum. The coating makeup is a duplex microstructure that results from the aluminum-rich phase solidifying first, as the coating cools, forming a network of dendrites. Interdendritic spaces are-filled by the zinc-rich phase. The intermetallic layer is an Al—Fe—Zn—Si alloy that metallurgically bonds the coating to the steel substrate and further aids in corrosion resistance. Such alloys are described in U.S. Pat. Nos. 3,343,930 and 3,393,089, which are incorporated herein by reference in their entireties.

Another aluminum-zinc coating alloy and its application is described in Friedersdorf et al., U.S. Pat. No. 6,468,674 (which is incorporated herein by reference in its entirety). In addition to zinc and aluminum, the alloy contains a small amount of certain carbides, borides, or aluminides. It is indicated that the alloy has better paintabilty and bending properties than an alloy without the added component.

Many variations on methods for applying zinc or zinc alloy coatings have been described. Examples include Sokoloski, U.S. Pat. No. 5,882,733; Ohbu et al., U.S. Pat. No. 3,962,501; Sippola, U.S. Pat. No. 5,958,518; Nakayama et al., U.S. Pat. No. 4,216,250 (one-sided coating); Dauchelle et al., U.S. Pat. No. 6,936,307; Ishii et al., U.S. Pat. No. 6,426,122; Gilles, U.S. Pat. No. 6,187,116; Flores, U.S. Pat. No. 5,989,645; Gunji et al., U.S. Pat. No. 4,275,098; Yoshida et al., U.S. Pat. No. 4,047,977 (coating part of a strip), each of which is incorporated herein in its entirety.

In methods for applying metal coatings containing hollow ceramic microspheres, in some cases it will be advantageous to apply hollow microspheres following initial application of a metal coating. Such application may be used to provide an initial incorporation of hollow microspheres or utilized as a second application of microspheres in order to maximize the overall porosity of the thermal barrier coating. For example, with hot dip coatings, following removal from the dip but before the coating has fully solidified, hollow microspheres (which may be additional hollow microspheres) can be applied to the surface in a manner such that they are bonded on and/or in the metal matrix of the coating, e.g., by spray and/or by rolling. To facilitate this process, the coated substrate can be held at an elevated temperature following the initial coating to allow sufficient time for an effective application of additional microspheres Microspheres which are not bonded can be removed, e.g., by blowing and/or by sweeping. Such recovered microspheres may be recycled for use. Such direct application of hollow microspheres is not limited to hot dip coatings, but can be used with other types of high temperature applications, e.g., thermal metal spray applications.

A method for coating metal with a metal coating containing ceramic microspheres is described in U.S. Pat. No. 6,916,529, which is incorporated herein by reference in its entirety. The method is used to improve the high temperature abradability of hot gas path metal components, such as shrouds in gas turbine engines. The methods can be adapted for application of the present thermal barrier coatings. As described therein, hollow microspheres, generally hollow ceramic microspheres, can be added to a metal matrix material to form a composite mixture and applied to a metal substrate. Such composite mixtures can be applied by conventional techniques, including but not limited to thermal metal spray, direct write followed by a sintering or consolidation treatment, and application as a complete layer followed by brazing. The methods described in U.S. Pat. No. 6,916,529 can be readily adapted to the present invention. Preferably the closed porosity levels are higher those indicated in that patent, that is, a higher proportion of hollow microspheres are incorporated. For example, coatings with greater than 50, 55, 60, 65, 70, or 75% porosity, or even higher, are desirable. Likewise, the coating thickness can be adapted to provide a desired level of reduction of thermal transfer rate.

As indicated above, metal coatings can be applied as thermal barrier coatings by the incorporation of components that reduce thermal conductivity. Particularly advantageous additives include hollow microspheres, e.g., microspheres that tolerate high temperatures such as a variety of ceramic microspheres. For coatings in which a molten metal is used, the microspheres should tolerate the temperature of the molten metal. Similarly, for coating processes that involve a heat treatment, the microspheres should tolerate any heat treatment to which they are subjected.

Further, compatible combinations of thermal barrier coating types can be used. For example, a paint type, cementitious, or bituminous coating can be applied over a metal coating. Likewise, a cementitious or bituminous coating can be applied over a paint type coating.

For any of the types of thermal barrier coatings, in most cases it is desirable to maximize the content of the coating component(s) that provide the thermal barrier properties. Thus, for example, for coatings that contain hollow microspheres, it is often desirable to maximize the volume percent of the final coating that is microsphere (consistent with maintaining needed coating strength and/or formability). To promote close packing of the microspheres, it can be helpful to minimize the binder component and/or to use more than one size of microsphere to allow closer packing. For example, two monodisperse sets of microspheres can be used where the second set is sized to fit within the interstices between packed microspheres of the first set resulting in more densely packed layers of microspheres.

### B. Exemplary Structural and Finish Members for Building Construction

Many different types of building members having thermal barrier coatings to reduce thermal transfer can be formed using the present process. Some examples are discussed below.

### 1. Structural Members

A number of different types of structural members can be coated with a thermal barrier coating to reduce thermal transfer. Such coating is most appropriate for structural members that would otherwise provide an undesirable, efficient heat flow path between environments that commonly are at substantially different temperatures, e.g., between the interior and exterior of a building or between heating and cooling ducts and surrounding spaces.

An especially common example of such a structural member is a steel stud. As pointed out above, typical steel studs very efficiently transfer heat between attached wall surfaces due to the heat flow path from one flange, across the web to the opposite flange. Such studs can be modified by coating at least the outward facing portion of one or both flanges. (If desired, additional portions or even the entire stud can be coated). Such coating(s) and the thickness used can be selected to provide a desired degree of reduction of thermal transfer through the stud (or other member).

In addition to simple coating of flange surfaces, the studs can be constructed such that other features of the stud also contribute to reduced heat flow across the stud. For example, a stud can be constructed such that it has reduced contact surfaces for attachment of wall surface material (e.g., reduced flange contact area). This can be accomplished by creating a channel(s) (i.e., one or more generally concave zones) on a contact surface so that only ribs or edges will contact an attached wall surface material. For example, the channel may create up to about ½ inch air gap, thereby reducing conductive heat flow through the resulting wall.

However, while such air gap reduces thermal transfer, the reduction is limited, e.g., due to conductive and radiative thermal transfer through the air in the channel. The reduction in thermal transfer can be significantly enhanced by coating the contact surface(s) with a thermal barrier coating. In addition, the reduced contact area of the simple channel design may be undesirable in many applications due to the reduction in stability of the connection between the stud and an attached material such as an interior or exterior wall material. Both of these limitations can be addressed by essentially filling the channel(s) with a thermal barrier coating. The thermal barrier coating filling the channel(s) restores full contact area for attaching wall material and further prevents significant deflection of the metal portion of the channel due to the use of penetrating fasteners such as drywall screws. Such filling can be relatively thick, e.g., 0.009-0.500 inch. If desired, the flange area may have ribs creating more than one channel on a flange. Alternatively, a relatively thick thermal barrier coating can be bonded to conventional flat flange surfaces. In this case the thermal barrier coating should be relatively strong to prevent significant compression or displacement of the coating.

Another example of a member that is designed to have reduced thermal transfer is a stud that has a substantially perforated webbing such that heat flow through the stud is reduced. In certain embodiments, the perforations include rolled or angled edges for reinforcement. For example, 60-80 percent of the metal can be removed from the web area. For any such design, the reduction in heat flow across the stud can be enhanced by coating at least the contact surfaces with a thermal barrier coating. Examples of studs with such web perforations are described in U.S. Pat. Nos. 4,909,007, 5,527,625, and 6,708,459, each of which is incorporated herein by reference in its entirety. A similar design can also be used for other types of structural members. In such members the contact edges or flanges can be coated with a thermal barrier coating to further reduce hear transfer and/or the flange area can be channeled as described above.

Further, studs can be constructed with channeled contact surfaces together with perforated web areas. These studs can also be coated with thermal barrier coating (e.g., on at least one contact surface). As indicated above, such coating can be a filling of the contact surface channel(s).

Other examples of structural members that can be formed include purlins, joists, rafters, tracks, trusses, roof pans, floor pans, decks, and the like.

### 2. Finish Members and HVAC Components

In addition to structural members, it can also be beneficial to reduce heat flow across certain finish members as well as across surfaces in HVAC systems. In many but not all cases, such finish members are part of the outer building envelope. Examples include roofing sections (e.g., raised rib roofing sections and roofing shingles), siding sections, doors, door frames, and window frames.

Finish members can be coated with a thermal barrier coating on one or both sides. In many cases, if only one side is to be coated, it will be the side that is toward the higher temperature zone or heat source.

Ventilation systems, and especially heating and air conditioning systems commonly contain extensive metal ducting for carrying conditioned air and/or exterior air. Frequently, the space surrounding the ducting is at a significantly different temperature resulting in large undesirable heat gain or loss unless insulation is supplied. Often, the insulation is supplied by surrounding the ducting with an external fiberglass or foam insulation. Advantageously, the present thermal barrier coating can be used to replace or supplement such insulation. The thermal barrier coating can be applied on one or both sides of the member. For example, where the thermal barrier coating is a supplement to external insulation on a heating duct, the thermal barrier coating can be applied to the inside of the duct or other HVAC member to reduce the initial thermal transfer into the metal of the member.

In some cases, it is advantageous to apply the thermal barrier coating before the member is formed. For example, the interior of duct section can be coated before roll-forming of the section by coating the appropriate surface of a metal strip that is used to form the duct section. Such prior coating facilitates uniform and efficient coating. Thus, pre-coated metal coil can be used, or a coating can be applied prior to roll-forming in a single process.

### 3. Sandwich Panels

In addition to the above building members, structural and/or architectural sandwich panels which include at least one metallic layer can advantageously include the present thermal barrier coatings. Such sandwich panels may include only structural layers or may also include finish or aesthetic outer layers, and/or may include insulative layers. Thus, for example, a sandwich panel may include a metallic outer layer, an insulative inner layer (e.g., foam), and another metallic outer layer. Such metallic outer layers (indeed any metallic layer in the sandwich) may include the present thermal barrier coatings on one or both surfaces of the metallic layer. In many case, the thermal barrier coating is more beneficial on the outer surface(s).

Of course, if a metallic layer is an interior layer in a sandwich panel or the interior surface of a surface metallic layer, that layer or surface will be coated before the sandwich panel is formed. However, in many cases, the metallic layer will be a surface layer and the coated surface will be an exterior or exposed surface. The thermal barrier coating in such cases will be applied in a manner consistent with the type of coating and the process of bonding the sandwich panel. For paint type thermal barrier coatings, if the sandwich bonding process does not substantially degrade or otherwise damage the coating, the coating may be applied either before or after the sandwich bonding. Of course, if the bonding would damage the coating, the the bonding will generally be performed first, followed by application of the thermal barrier coating. For more durable coatings, such as metal thermal barrier coatings, the coating may usually be applied either before or after the sandwich bonding, as desired.

The metallic layers in such sandwich panels can be formed using conventional means, which will depend on the surface profile desired and the characteristics of the metal involved (usually a steel or aluminum layer). For example, such layers may be formed by pressing, stamping, roll forming, and the like.

### 4. Fasteners for Building Members

In addition to the thermal barrier coated building members (e.g., as described above), it can be useful to also provide thermal barrier coated fasteners. Such fasteners will commonly be used to fasten the present building members together or to fasten a present building member and another building component together, e.g., fastening drywall to steel studs or fastening roof sheathing to roof trusses. In such cases, the metal to metal contact of fasteners lacking thermal barrier coating with the metal building members at the point where the fastener penetrates the building member can provide a point of high thermal conductivity.

Such high thermal conductivity can be reduced by using thermal barrier coating on at least some of the contact surfaces, especially the metal to metal contact surfaces. Thus, for screw fasteners, advantageously, at least the threaded portion in contact with a building member is coated with a thermal barrier coating, thus reducing the heat transfer across the thread contact portion. In addition, all or at least a contact portion of the head of screw fasteners can beneficially be coated with thermal barrier coating, e.g., at least the underside of the head. Cap screws can be coated similarly, such that at least some of the portions of the cap screw which will be metal-to-metal contact during normal installation are coated with a thermal barrier coating, e.g., at least the underside of the head and/or the penetrating portions. For the use of bolts (cap screw and nut combinations), all or at least a contact portion of the nut can be coated. In many cases, washers are used with bolts; thus, advantageously the washers can be coated.

The coating selected should be sufficient durable to withstand installation and use. For surfaces which will not be subjected to strong abrasion, a paint type coating will usually be sufficient, although other coating types can be used. For surfaces which will be subjected to strong abrasion (e.g., the threads of self-tapping metal screws) it may be advantageous to use a powder coat or metal thermal barrier coating, e.g., of a type as indicated above.

### C. Roll Forming Structural Members from Metal Coils

In many applications, it is advantageous to be able to form structural members using a roll-forming line, either using metal coil that is pre-coated with thermal barrier coating, or applying such coating prior to forming as part of a continuous forming and finishing process. In either case, it is desirable to use a thermal barrier coating that is able to withstand the requisite bending that occurs during the forming process.

In cases where the desired coating will not tolerate the bending without damage to the coating, another thermal barrier coating can be applied after the desired shape is formed to repair any damage that may have occurred (and/or to supplement the thermal barrier provided by the pre-coat). Alternatively, forming can be performed using uncoated metal coil, and the formed product then coated on a desired surface or surfaces with thermal barrier coating. Typically such post-forming coating will involve preparatory surface cleaning steps to promote adhesion of the thermal barrier coating. In some cases the forming is performed continuously on the metal coil. In such cases, the post-forming thermal barrier coating can be applied to the continuous formed material, which is then cut to desired lengths, or the material is cut to length either before or after forming and the formed, cut-to-length member is thermal barrier coated.

In addition to roll forming of structural members, other forming methods may be used to form metal items from thermal barrier coated sheets or coils, or with thermal barrier coating applied after the forming. For example, stamping or pressing may be used to produce contoured door panels which can then be used to fabricate doors, e.g., residence and garage doors. In yet other cases, desired bends can be created using a brake, e.g., for relatively simple profiles.

The process and systems for producing building members that have thermal barrier coatings can produce such items at the same or similar rates as roll forming of such members lacking those coatings. The production rates are applicable to a variety of systems and processes, including the use of pre-coated metal coil, re-coating of metal coil following forming, and initially coating the coil or the formed members in an essentially continuous process and system of forming and coating (where the coating can occur before and/or after the forming). Thus, in particular systems and processes, the production of roll formed members that include at least one thermal barrier coated surface is at least 100 ft/min, e.g., at least 150, 200, 300, or 400 ft/min, or 100-300, 200-400, 300-500 ft/min.

### D. Steel Coil Processing Systems

In addition to simply concerning methods for forming thermal barrier coated building members and the resulting coated products, the present invention concerns systems for processing steel to provide thermal barrier coated steel coils and/or formed building members that have a thermal barrier coating.

Thus, the invention concerns a variety of systems that include at least a coil handling system (e.g., a coiler and/or uncoiler) and a thermal barrier coating system. Such a system can be designed to utilize already coiled metal strip or can be part of a metal strip production facility that both produces and coats the metal strip, e.g., metal coil. As a result, the systems can include a variety of different combinations of additional components. Examples include hot and/or cold rollers, strip welder, pickling tank, de-oxidizing furnace, strip slitter, coil straightener, annealing oven, curing or drying oven, and other such components.

For example, a system that produces the initial strip can include components conventional for such productions, e.g., hot and/or cold rollers, strip welder, picking tank, de-oxidizing furnace. Once the strip of desired thickness is produced, it can be delivered directly or as a coil to a coating line that applies one or more coatings. For the present invention, at least one of the coatings is a thermal barrier coating.

An exemplary system that includes both thickness rolling and a coating line for providing coated metal strip is described in Kajiwara et al., U.S. Pat. No. 5,463,801. Such system can be adapted to the present invention by providing a coating line that applies a thermal barrier coating to the strip.

Some systems are set up to use metal coil that does not include a thermal barrier coating. Such systems may be arranged to apply the thermal barrier coating and then re-coil the strip, or can include at least one forming line, e.g., a roll-forming line or a sheet stamper or press. Systems that include a forming line can advantageously also include a coil straightener and/or a coil slitter.

In systems that include a forming line, the thermal barrier coating may be applied before and/or after the forming is completed. Where the thermal barrier coating is applied before the forming, the thermal barrier coating should be selected to tolerate the type and extent of bending applied by the forming line, although another thermal barrier coating layer can be applied after forming to repair bending-created damage to the initial thermal barrier coating.

For example, a coil may be supplied having a metal thermal barrier coating, such as a zinc-aluminum alloy coating containing a high concentration of hollow ceramic microspheres. After forming, one or more surfaces can be coated with a layer(s) of a paint-type, thermal coat, and/or other desired type of thermal barrier coating that will cover the initial metal thermal barrier coating and seal any damage that may be present. Of course, such additional coats of thermal barrier coating may be applied post-forming even if the forming process does not cause detrimental damage to the initial thermal barrier coating.

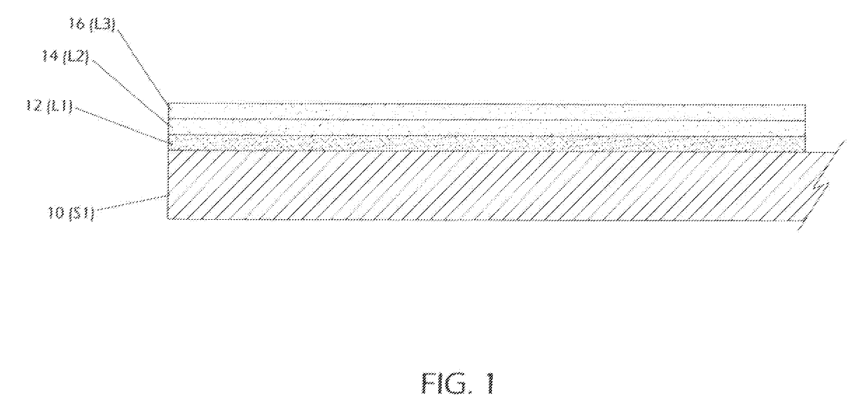

The present invention is further illustrated by reference to the drawings. A coated sheet with multiple coating layers is shown schematically in FIG. 1. The metal substrate 10 has sequentially applied thermal barrier coating layers L1 12, L2 14, and L3 16. In such a coating system, L1 may be a primer coat, L2 a build coat, and L3 a top coat.

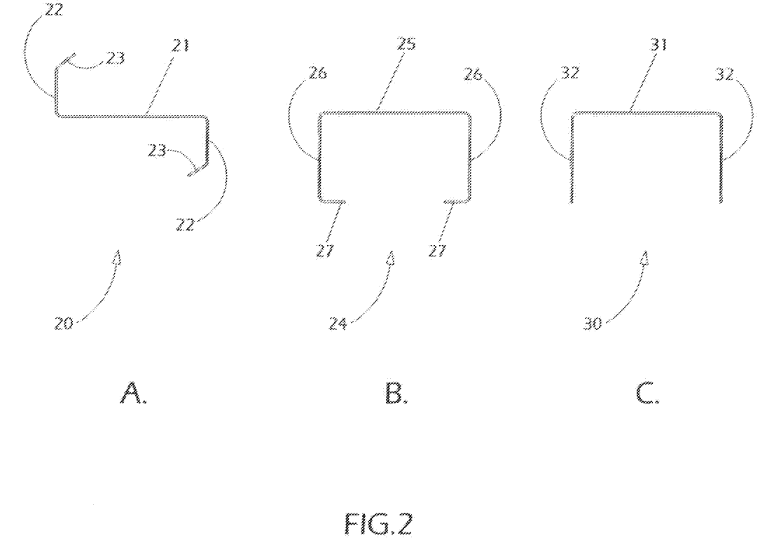

Three exemplary roll-formed, structural member profiles are illustrated in FIGS. 2A, 2B, and 2C. FIG. 2A shows a cross-section of a Z-purlin 20, including web 21, screw flanges (or legs) 22, and stiffener flanges (or returns) 23. FIG. 2B shows a cross-section of a C-purlin or other C-member 24 that includes web 25, screw flanges (or legs) 26 and stiffener flanges (or returns) 27. FIG. 2C shows a cross-section of a simpler U-member 30 (e.g., a track), that includes web 31, and screw flanges (or legs) 32. Each of these members can be coated on the outside face of the screw flanges and/or other contact surfaces with a thermal barrier coating, reducing the heat flow through a wall, roof, or other surface which includes sheeting material attached to the screw flange of the member.

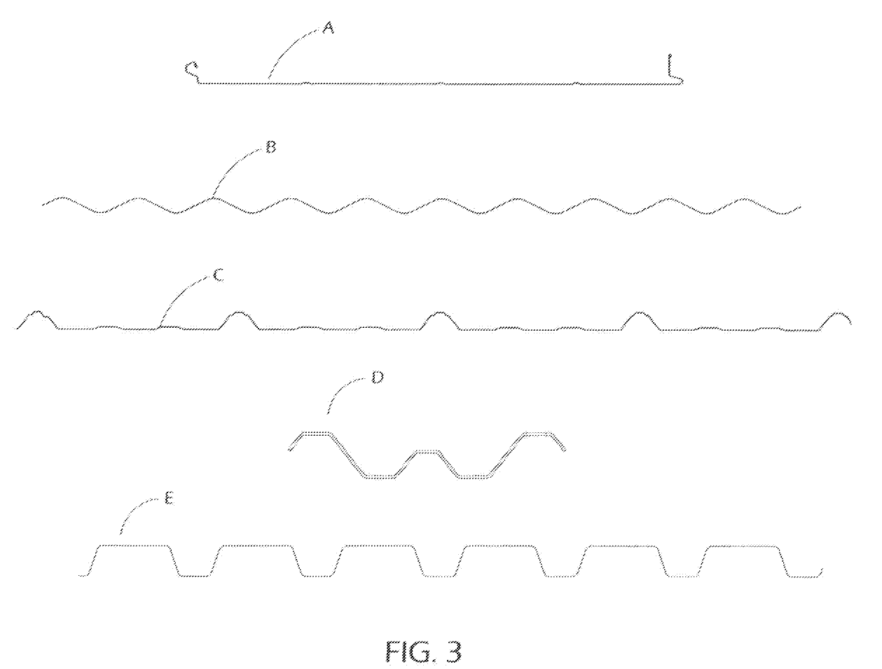

Similarly, FIG. 3 shows cross-section profiles of three different roofing panels, a wall stiffener, and a floor deck, those being A. standing seam roofing panel, B. corrugated roofing panel, C. spaced rib roofing panel, D. wall stiffener, and E. floor deck. On each of the illustrated panels (as well as other such panels with other profiles) thermal barrier coating can be applied on one or both sides to improve thermal barrier properties of the building surface.

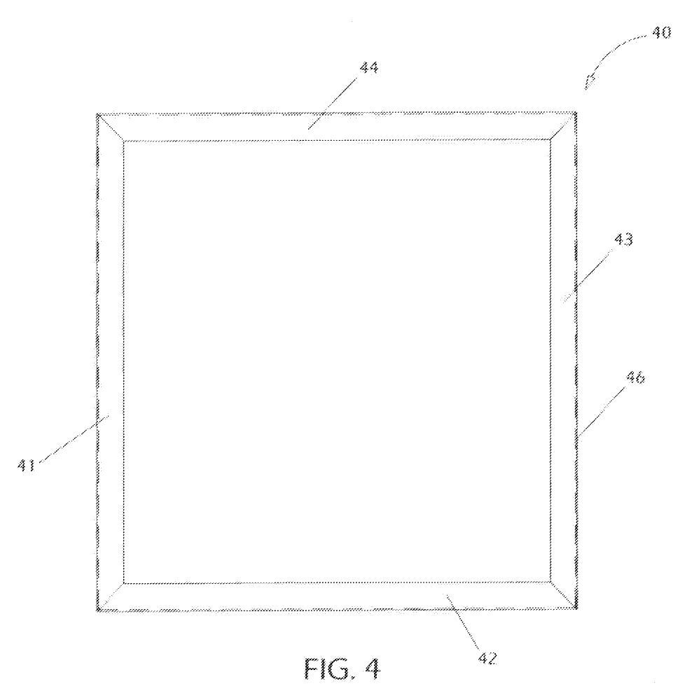

FIG. 4 shows a roll formed emergency egress opening frame (e.g., for installation in concrete walls). The frame 40 includes four roll formed sections 41, 42, 43, and 44 joined at the corners. A thermal barrier coating 46 is present on the perimeter of the frame, such that it forms a thermal barrier between the frame and the concrete of a concrete wall in which it would be installed. Thermal barrier coating can also advantageously be applied on the other surfaces of the frame.

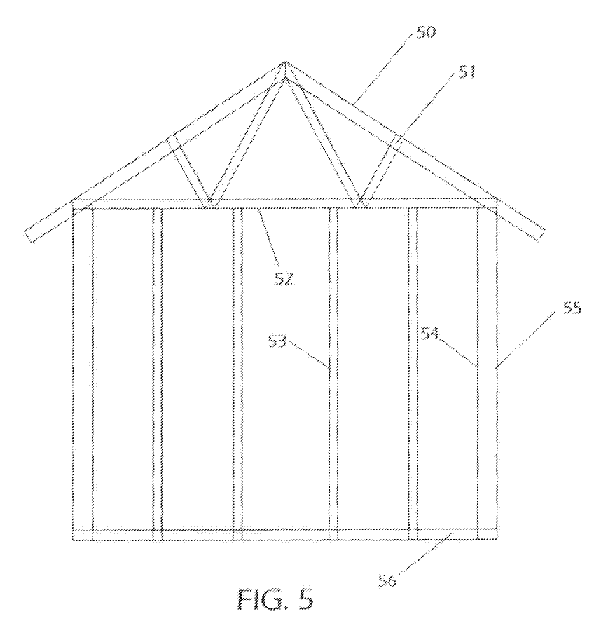

FIG. 5 schematically illustrates a number of different locations on a steel framed building where use of thermal barrier coated structural members provides an advantageous thermal barrier. These include, for example, rafter flanges 50 (if metal roofing is used use of thermal barrier coated roofing panels is also beneficial), connection surfaces 51 between members, surfaces 52 contacting interior ceiling sheeting, stud surfaces 53 that will contact exterior sheeting, siding or the like, stud surfaces 54 that will contact interior sheeting, and siding surfaces 55 if metal siding is installed.

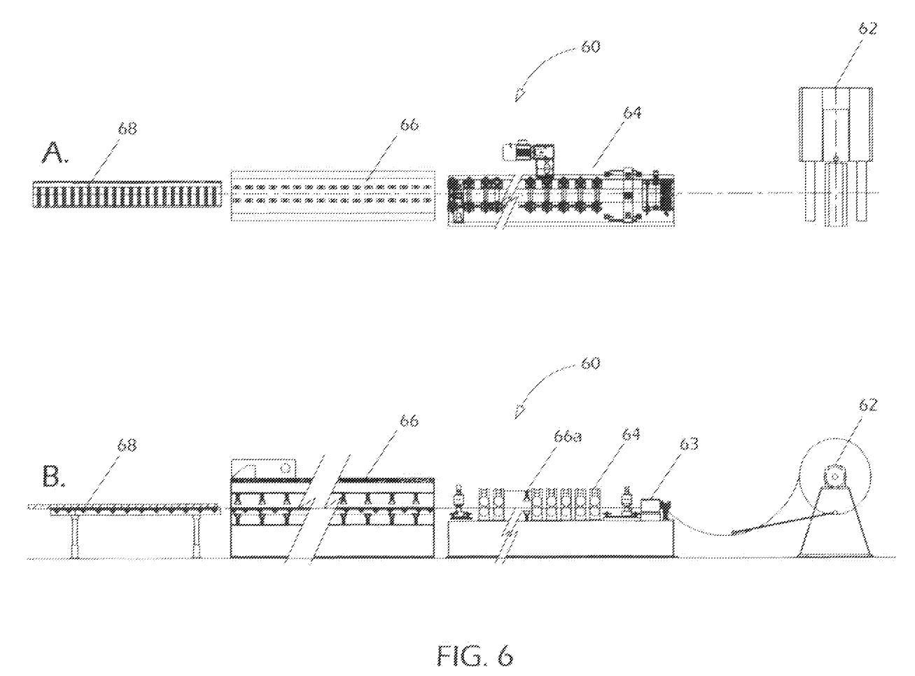

FIG. 6 illustrates a simplified, combined roll forming and thermal barrier coating line 60 showing side view A and top view B. The line includes uncoiler 62, coil straightener 63, roll former 64 (which can include optional spray unit 66a) coating and drying unit 66, and cooling conveyor 68. In such a system, usually uncoated coil is used, and thermal barrier coating is applied in the process of production of building members. Alternatively, pre-coated coil is used, and a repair or additional layer of thermal barrier coating is applied following the roll forming operation. Of course, it is understood that additional components may be incorporated in such a production line, e.g., additional coating and/or drying units, punch presses, coil cleaners, automated material handling robots, and the like.

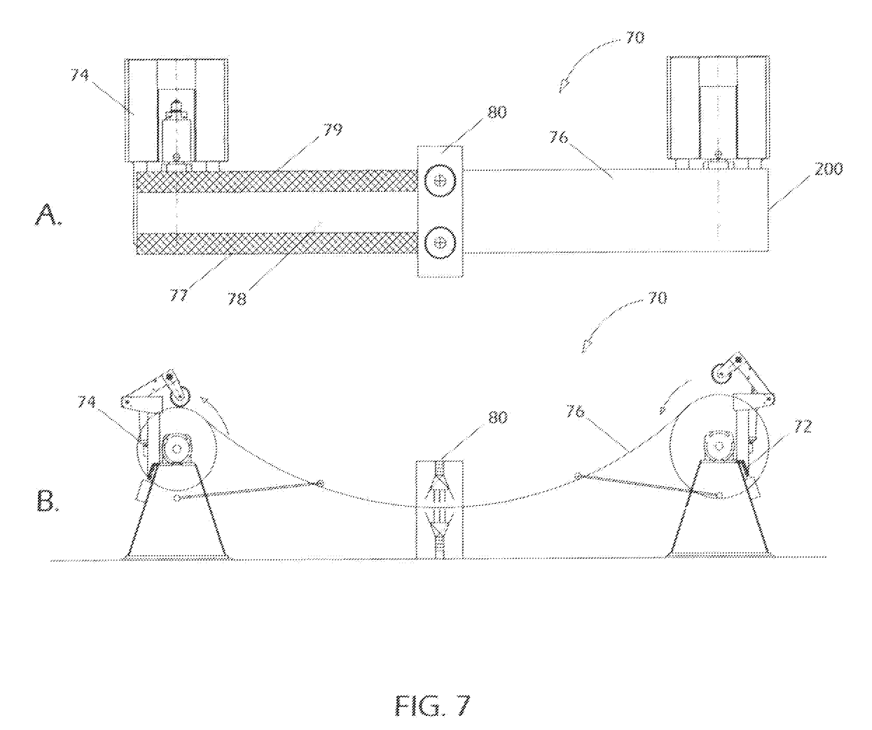

FIG. 7 shows a simplified system 70 for coating metal coil with thermal barrier coating using spray application, showing a top view A and side view B. Such system includes uncoiler 72 on which an uncoated coil is mounted, sprayer 80 which can spray one or more longitudinal bands 77 and 79 and can leave one or more longitudinal bands 78 on the metal strip 76. After coating and drying, the metal strip (now coated) is re-coiled on re-coiler 74. Commonly, a system for producing thermal barrier coated coil may also include other components, such as a dryer and/or a coil cleaner.

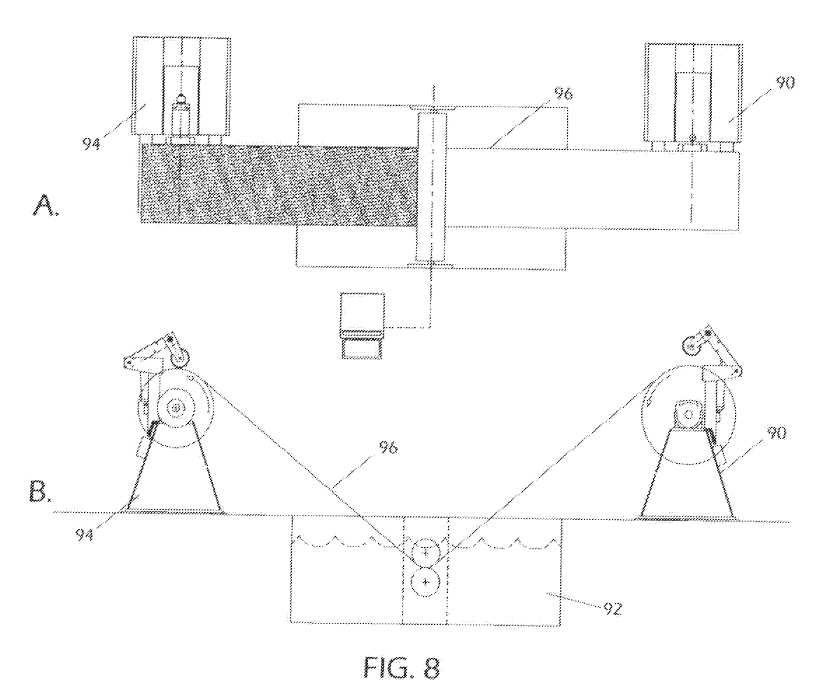

FIG. 8 shows a simplified version of a thermal barrier coating system for coating metal coil with a thermal barrier coating using dip application, e.g., hot dip application such as for applying metal coatings, with top view A and side view B. The system includes an uncoiler 90 on which coil to be coated is mounted, dip tank 92, and re-coiler 94 on which the coated strip is taken up and re-coiled into a coated coil. Usually the coil is fully coated on both sides, but techniques are known and can be used to coat only one side and/or to coat only a longitudinal band that does not extend the full width of the strip. As with a spray system, the present dip system will often include additional components, e.g., heaters, ovens, roll presses, and the like.

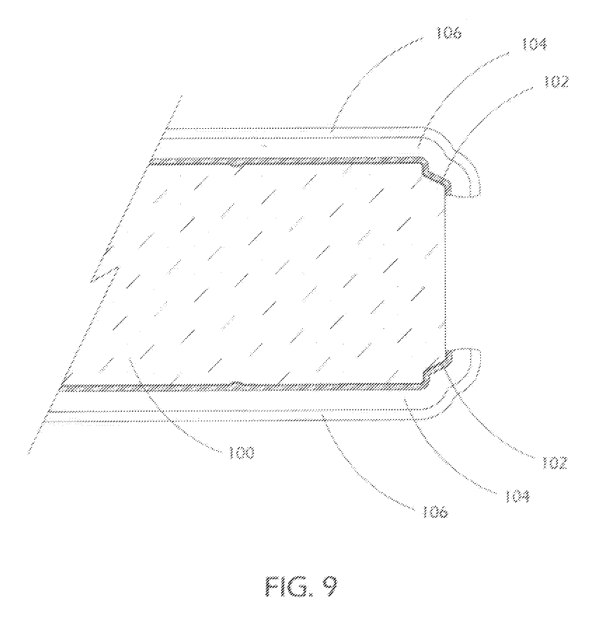

FIG. 9 shows an exemplary sandwich panel construction incorporating the present thermal barrier coatings. As illustrated, the sandwich panel includes an insulating core 100 (e.g., a foam plastic core), bonded top and bottom to steel sheets 102. The steel sheets are coated on the exterior with thermal barrier coating 104 (e.g., a metal and/or paint coating containing a higher proportion of hollow microspheres, and top coated with finish coating 106.

### E. Study and Analysis for Improving Energy Performance of Steel Stud Walls

A useful article on various steel studs and the analysis of such studs incorporated in a variety of different wall panel designs was published on-line for Oak Ridge National Laboratory as the article IMPROVING ENERGY PERFORMANCE OF STEEL STUD WALLS: Steel Framing Can Perform As Well As Wood, by Jan Kosny, Jeffrey E. Christian, and André O. Desjarlais of Oak Ridge National Laboratory, Buildings Technology Center, which is incorporated herein by reference in its entirety. Printed copies of the article are also available directly from Oak Ridge National Laboratory. The description of the article was also included in provisional application Jensen, Appl. No. 60/863,798, filed Oct. 31, 2006, which is incorporated herein by reference in its entirety. This article provides a variety of different wall studs and structures to which the present thermal barrier coatings can be usefully applied. Thus, in particular embodiments the building member is as described in the following description and associated drawings. The article also provides information and methods for analyzing the thermal transfer characteristics for walls and other bulding panels.

A computer analysis of the thermal performance of steel stud walls was carried out by the authors based on the clear wall perspective. Currently, most of the simplified thermal calculations for steel stud wall systems are based on the measured or calculated thermal performance of the flat wall area without the effect of the wall details included. In this paper, this method is called the “clear wall” method. The clear wall is understood as the part of the wall that is free of thermal anomalies due to wall details (i.e., windows or doors' perimeters) or intersections with the other building surfaces.

In this paper, the analysis is based on test results and on two- and three-dimensional computer modeling. To aid in the understanding of the thermal performance of steel stud walls, a series of twenty configurations of the steel stud walls was simulated. A finite difference computer code was used to model walls. Maps of the temperature distribution (isotherms) in walls were developed. These isotherms were used to calculate effective R-values. Using simulated R-values, several configurations of wall insulation were examined.

Very often, thermal performance of the steel stud wall is compared with wood stud wall. A reduction of the in-cavity R-value caused by the wood studs is about 10% in wood stud walls. In steel stud walls, thermal bridges generated by the steel components, reduce their thermal performance by up to 55%. Today, steel stud walls are believed to be considerably less thermally effective than similar systems made of wood because steel has a much higher thermal conductivity than wood. Relatively high R-values may be achieved by installing insulating sheathing, which is now widely recommended as the remedy for a weak thermal performance of steel stud walls.

Of the series of steel stud wall configurations analyzed, some walls were designed and tested by the authors, some were tested in other laboratories, and some were developed and forgotten a long time ago. Several types of thermal breaking systems were used in these walls:

Insulating sheathing;

Several types of distance washers (spacers) to reduce contact area between the steel studs and exterior sheathing;

Reflective surfaces were added to spacer systems to improve R-value of air space;

Studs with reduced stud depth area or two rows of studs;

Several unconventional shapes of studs;

Local foam insulation for studs, and

A novel concept of combined foam/steel studs.

In addition to the two- and three-dimensional finite difference computer simulations used to analyze the steel stud wall configurations, a series of ASTM C 236 hot-box tests were conducted on several of these walls. Test results for twenty-two additional steel stud walls were analyzed. Most of these walls contained conventional C-shape steel studs. Commonly used fiberglass and EPS were used as an insulation material. In many of the tested walls, the R-value exceeded 16 hft²F/Btu (2.81 m²K/W). The most promising steel stud wall configurations have reductions of the center of cavity R-values below 20%.

In many cases, commercially available steel stud wall systems were initially designed by simple replacement of wood studs, joists, headers, etc., by structurally equivalent steel components. Steel substitutes of the wood structure are very often being installed without consideration of the difference in thermal conductivity between wood and steel. Strong thermal bridges caused by highly conductive steel components worsen thermal performance of these walls. Because steel has higher thermal conductivity than wood, intense heat transfer occurs through the steel wall components. Wall R-value reductions (Framing Effects) caused by studs (as functions of the level of exterior insulation sheathing and stud spacing) were estimated and compared for all considered cases.

Several wall configurations are being developed to improve steel frame system thermal performance. Some of these innovations are evaluated in this paper. The most popular way to improve the thermal performance of steel stud walls is installing exterior insulation sheathing. Some designers try to reduce thermal bridge effects generated by the steel stud by installing horizontal steel, or wooden spacers that reduce the contact area between studs and wall finish layers. Another way to minimize the contact area between studs and sheathing material is achieved by forming small dimples on the stud flange surfaces. Also, some building material producers claim that the improvement in steel stud walls' thermal performance may be obtained by increasing the area of the holes located on the stud web. Some unconventional shapes of steel studs are discussed as well.

The study included simulation and experimental results for several configurations of steel stud walls containing thermal breaking systems. Most walls were constructed in the conventional way. They consisted of the interior board layer, wall cavity (insulated, or not), exterior sheathing layer, and exterior finish. Several types of insulating techniques for steel stud walls were evaluated. In some walls, two types of spacers were used to separate studs from the sheathing material. Wood and steel spacers reduced the contact area between stud flanges and the exterior layer of the wall. Also, the thermal performance of walls containing unconventionally shaped steel studs, or combined foam-steel studs were analyzed.

The present invention can beneficially be used on the steel portions of the wall studs described and tested in this article, as well as on similar building members used for other building surface and panels.

All patents and other references cited in the specification are indicative of the level of skill of those skilled in the art to which the invention pertains, and are incorporated by reference in their entireties, including any tables and figures, to the same extent as if each reference had been incorporated by reference in its entirety individually.

One skilled in the art would readily appreciate that the present invention is well adapted to obtain the ends and advantages mentioned, as well as those inherent therein. The methods, variances, and compositions described herein as presently representative of preferred embodiments are exemplary and are not intended as limitations on the scope of the invention. Changes therein and other uses will occur to those skilled in the art, which are encompassed within the spirit of the invention, are defined by the scope of the claims.

It will be readily apparent to one skilled in the art that varying substitutions and modifications may be made to the invention disclosed herein without departing from the scope and spirit of the invention. For example, variations can be made to the particular type of thermal barrier coating and to the type of member being formed. Thus, such additional embodiments are within the scope of the present invention and the following claims.

The invention illustratively described herein suitably may be practiced in the absence of any element or elements, limitation or limitations which is not specifically disclosed herein. Thus, for example, in each instance herein any of the terms “comprising”, “consisting essentially of” and “consisting of” may be replaced with either of the other two terms. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In addition, where features or aspects of the invention are described in terms of Markush groups or other grouping of alternatives, those skilled in the art will recognize that the invention is also thereby described in terms of any individual member or subgroup of members of the Markush group or other group.

Also, unless indicated to the contrary, where various numerical values or value range endpoints are provided for embodiments, additional embodiments are described by taking any 2 different values as the endpoints of a range or by taking two different range endpoints from specified ranges as the endpoints of an additional range. Such ranges are also within the scope of the described invention.

Thus, additional embodiments are within the scope of the invention and within the following claims.

1. A process for preparing a building member, comprising
unwinding a metal coil of a particular thickness;
coating at least a longitudinal band of said metal coil with a thermal barrier coating to provide a coated sheet; and
roll-forming a building member from said coated sheet, wherein the coating is present on at least one contact surface of said building member.

2. The process of claim 1, wherein said coating is performed before said roll-forming.

3. The process of claim 1, wherein said roll-forming is performed before said coating.

4-7. (canceled)

8. The process of claim 1, wherein said thermal barrier coating is a paint.

9. (canceled)

10. The process of claim 1, wherein said thermal barrier coating is a metal coating.

11-15. (canceled)

16. The process of claim 1, further comprising applying at least a second coating of thermal barrier material following said roll-forming.

17. (canceled)

18. The process of claim 1, wherein said building member is a wall stud.

19-27. (canceled)

28. The process of claim 1, wherein said thermal barrier coating comprises a thermal barrier permanent metal coating and a thermal barrier paint coating.

29. A process for finishing a metal coil, comprising
coating at least a longitudinal band of a metal strip of a particular thickness with a thermal barrier coating; and
following said coating, coiling said metal strip as a coated metal coil.

30-32. (canceled)

33. The process of claim 29, wherein said thermal barrier coating is a thermal barrier paint.

34. (canceled)

35. The process of claim 29, wherein said thermal barrier coating is a permanent metal coating.

36-39. (canceled)

40. A process for making a building member, comprising
forming a thermal barrier coated meal coil of a particular thickness into a building member.

41. The process of claim 40, wherein said forming comprises roll-forming.

42. The process of claim 40, wherein said forming comprises stamping.

43. (canceled)

44. The process of claim 40, wherein the thermal barrier coating on said metal coil comprises a thermal barrier paint coating.

45. The process of claim 40, wherein the thermal barrier coating on said metal coil comprises a thermal barrier metal coating.

46-60. (canceled)

61. A thermal barrier coated metal coil, comprising
a coil of metal sheet, wherein said sheet comprises at least a longitudinal band coated on at least one side with a thermal barrier coating.

62. (canceled)

63. (canceled)

64. The thermal barrier coated metal coil of claim 61, wherein said longitudinal band is coated on both sides.

65. (canceled)

66. The thermal barrier coated metal coil of claim 61, wherein said thermal barrier coating comprises a thermal barrier paint.

67. The thermal barrier coated metal coil of claim 61, wherein said thermal barrier coating comprises a thermal barrier metal coating.

68. (canceled)

69. (canceled)

70. A formed metal building member, wherein said member comprises a thermal barrier coating on at least one surface.

71. The building member of claim 70, wherein said member is roll-formed.

72. (canceled)

73. (canceled)

74. The building member of claim 70, wherein said thermal barrier coating comprises a paint.

75. (canceled)

76. The building member of claim 70, wherein said thermal barrier coating comprises a metal coating.

77. (canceled)

78. The building member of claim 70, wherein said thermal barrier coating comprises hollow microspheres.

79. (canceled)

80. The metal building member of claim 70, wherein said building member is a structural member and said surface is a contact surface.

81. (canceled)

82. The building member of claim 80, wherein said member is a stud.

83-99. (canceled)

100. A thermal barrier steel wall stud, comprising
a longitudinal member, wherein said member comprises a web and two peripheral flanges, wherein said peripheral flanges are coated on their outer surfaces with a thermal barrier coating.

101-116. (canceled)

117. A steel coil processing system, comprising
a coil handling mechanism;
a coating reservoir containing a thermal barrier coating material, and
a thermal barrier coating system, wherein said thermal barrier coating material is applied to said steel coil.

118-132. (canceled)
